(19) United States
(12) Patent Application Publication
(10) Pub. No.: US 2010/0314245 A1
(43) Pub. Date: Dec. 16, 2010

(54) Ionized Physical Vapor Deposition for Microstructure Controlled Thin Film Deposition

(75) Inventors: Karl Brown, Los Gatos, CA (US); Alan Ritchie, Menlo Park, CA (US); John A. Pipitone, Livermore, CA (US); Daniel J. Hoffman, Saratoga, CA (US); Ying Rui, Santa Clara, CA (US); Donald J.K. Olgado, Palo Alto, CA (US)

Correspondence Address: DIEHL SERVILLA LLC, 33 WOOD AVE SOUTH, SECOND FLOOR, SUITE 210, ISELIN, NJ, 08830, US

(73) Assignee: Applied Materials, Inc., Santa Clara, CA (US)

(21) Appl. No.: 12/483,779

(22) Filed: Jun. 12, 2009

(51) Int. Cl. C23C 14/34

(52) U.S. Cl. 204/192.15; 204/192.12

(57) ABSTRACT

Methods of processing a substrate in a PVD chamber comprising a target, a substrate and a process gas at a pressure sufficient to cause ionization of a substantial portion of species sputtered from the target are described. A capacitively coupled high density plasma is maintained by applying very high frequency power to the target. Sputtered material is ionized in the plasma and accelerated toward the substrate by a high frequency bias power applied to the substrate. The microstructure of the resultant film is controlled by modifying one or more of the pressure and the high frequency bias power.

### BACKGROUND

Embodiments of the present invention related to methods for depositing a material using physical vapor deposition. Specifically, embodiments of the invention are directed to methods for creating a high density plasma resulting in target ion formation for directional sputtering of a controlled microstructure film.

Photovoltaic technology is of great interest due to the desire to achieve an energy supply that is independent of fossil fuels. In spite of the fact that thin film solar cell technology has been researched at an increased pace lately, silicon technology still generates the largest revenues. The reason is not only that this technology is the most mature one, but also because the most efficient solar cells can be produced with it.

Photovoltaic devices, or solar cells, are devices which convert sunlight into direct current (DC) electrical power. Photovoltaic devices typically have one or more p-n junctions. Each junction comprises two different regions within a semiconductor material where one side is denoted as the p-type region and the other as the n-type region. When the p-n junction of the photovoltaic cell is exposed to sunlight (consisting of energy from photons), the sunlight is directly converted to electricity through the photovoltaic effect. Photovoltaic cells generate a specific amount of electric power and cells are tiled into modules sized to deliver the desired amount of system power. Photovoltaic modules are created by connecting a number of photovoltaic solar cells and are then joined into panels with specific frames and connectors.

Several types of photovoltaic devices including microcrystalline silicon films (μ-Si), amorphous silicon films (a-Si), polycrystalline silicon films (poly-Si) and the like are being utilized to form photovoltaic devices. The microstructure of the silicon film has various effects on the overall performance of a photovoltaic cell.

There is a need in the art for improved methods for depositing films with controlled micro structures.

### SUMMARY

One or more embodiments of the invention are directed to methods of processing a substrate in a physical vapor deposition (PVD) vacuum chamber. The processing method comprises providing a target adjacent a ceiling of the chamber. A substrate is placed on a support facing the target. A process gas is introduced into the chamber to a selected pressure. The pressure being sufficient to cause ionization of a substantial portion of the species sputtered from the target. A capacitively coupled high density plasma is maintained by applying a first power at a first frequency to the target. The frequency is sufficiently high to excite kinetic electrons. A second power is applied to the substrate at a second frequency which is lower than the first frequency. The second power at the second frequency generates a sheath potential sufficient to deposit a film of sputtered ions from the plasma. One or more of the selected pressure and the sheath potential is controlled to control the microstructure of the film.

According to one or more embodiments, the target is selected from the group consisting of silicon, doped silicon, zinc oxide, indium tin oxide, transparent conductive oxide, metals and combinations thereof. In some embodiments, there is substantially no direct current power is applied to the target.

In detailed embodiments, the selected pressure is in the range of about 6 mTorr to about 140 mTorr, or in the range of about 40 mTorr to about 70 mTorr. In detailed embodiments, the first frequency is about 60 MHz and the first power is about 4 kW. In detailed embodiments, the second power is in the range of about 0 watts to about 600 watts. In detailed embodiments, the second frequency is about 2 MHz or about 13.56 MHz. The second frequency of specific embodiments is effective to cause ions within the plasma to move perpendicularly toward the substrate.

In some embodiments, a third power at third frequency applied to the target, the third frequency in the range of about 400 kHz to about 14 MHz to increase the sputter rate from the target, the third power in the range of about 500 watts to about 2 kilowatts.

In detailed embodiments, the method further comprises adjusting one or more of the selected pressure and the first frequency to change number of ions hitting the substrate. In detailed embodiments, the method further comprises adjusting the second power to change the energy of the sputtered ions. In detailed embodiments, the method further comprises controlling the temperature of the substrate.

In some embodiments, the process gas comprises argon. In detailed embodiments, the process gas further comprises a percentage of hydrogen. In specific embodiments, the percentage of hydrogen is up to about 30%, or in the range of about 2% to about 10%, or about 2.8%.

In detailed embodiments, the target comprises silicon and the percentage of hydrogen is controlled to reduce silicon dangling bonds in the film.

One or more embodiments of the invention are directed to methods of processing a substrate in a physical vapor deposition (PVD) vacuum chamber. The method includes performing a deposition step with deposition parameters comprising a plasma pressure, very high frequency power and high frequency power. The deposition comprises providing a target adjacent a ceiling of the chamber; placing a substrate on a support facing the target; introducing a process gas into the chamber to a selected pressure; generating a high density plasma from the process gas by applying very high frequency power to the target, generating a sheath potential by applying high frequency power to the substrate, the high frequency power being sufficient to substantially ionize material sputtered from the target; depositing a film on the substrate from the ions generated from the material sputtered from the target; and controlling microstructure of the film by adjusting one or more of the selected pressure and high frequency power.

In detailed embodiments the pressure is reduced and the high frequency power is reduced to form an amorphous film. In detailed embodiments, one or both of the high frequency power and the pressure is increased to increase sputtered ion flux or ion energy to form a crystalline film. In some detailed embodiments, the target comprises silicon and the process gas comprises a mixture of argon and hydrogen, the mixture being effective to reduce dangling silicon bonds in the film. In specific embodiments, the substrate comprises a solar cell.

### BRIEF DESCRIPTION OF THE DRAWINGS

FIG. 1 is a schematic cross-sectional view of one embodiment of a process chamber in accordance with an embodiment of the invention;

FIG. 2 is a graph of the power distribution as a function of VHF frequency in accordance with an embodiment of the invention;

FIG. 3 is a graph of the ion energy distribution density as a function of mixing 13.56 MHz and 2 MHz bias frequencies in accordance with an embodiment of the invention;

FIG. 4 is a transmission electron micrograph of a multilayer film formed according to an embodiment of the invention;

FIG. 5 is a transmission electron micrograph of a multilayer film formed according to an embodiment of the invention; and

FIG. 6 is a transmission electron micrograph of a multilayer film formed according to an embodiment of the invention.

### DETAILED DESCRIPTION

Before describing several exemplary embodiments of the invention, it is to be understood that the invention is not limited to the details of construction or process steps set forth in the following description. The invention is capable of other embodiments and of being practiced or being carried out in various ways.

As used in this specification and the appended claims, “substantial ionization”, “substantially ionized”, “ionization of a substantial portion” and the like, means that the ionization is greater than about 5% of the total species.

As used in this specification and the appended claims, the term “very high frequency” or “VHF” refers to frequencies in the range of about 40 MHz to about 100 MHz. As used in this specification and the associated claims, the term “high frequency” or “HF” refers to frequencies up to about 40 MHz, but generally not below about 400 kHz. The term “ultra-high frequency and “UHF” refer to frequencies greater than about 100 MHz.

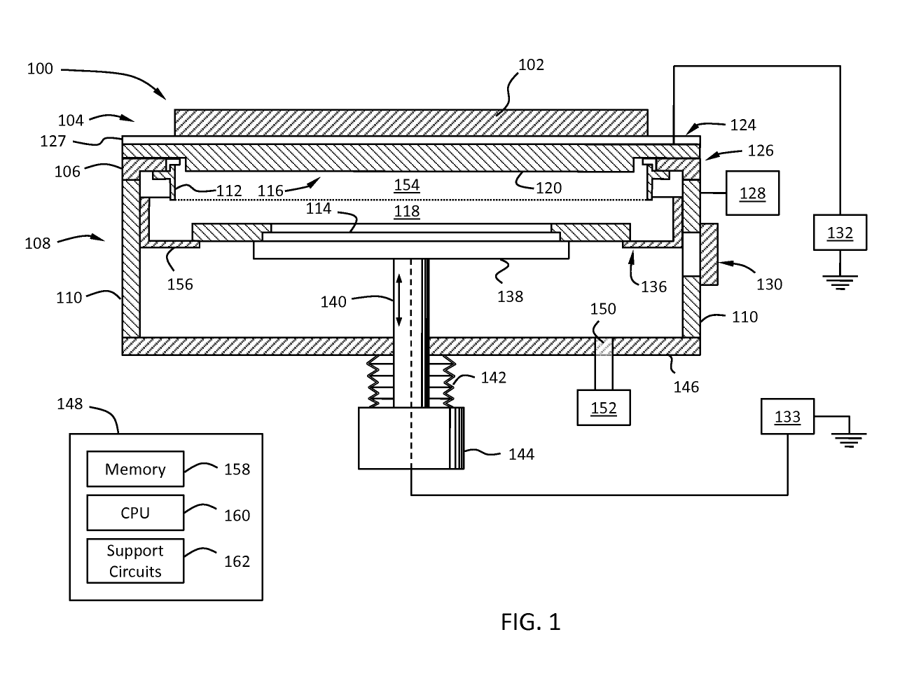

FIG. 1 illustrates an exemplary physical vapor deposition (PVD) chamber 100, also referred to as a “sputtering chamber”, “process chamber”, or a “sputter process chamber”, suitable for sputter depositing materials according to one or more embodiment of the invention. The process chamber 100 includes a chamber body 108 having a processing volume 118 defined therein. The chamber body 108 has sidewalls 110 and a bottom 146. The dimensions of the chamber body 108 and related components of the process chamber 100 are not limited and generally are proportionally larger than the size of the substrate 114 to be processed. Any suitable substrate size may be processed and the size of the processing chamber 100 can be potentially unlimited.

A chamber lid assembly 104 is mounted on the top of the chamber body 108. The chamber body 108 may be fabricated from aluminum or other suitable materials. A substrate access port 130 is formed through the sidewall 110 of the chamber body 108, facilitating the transfer of a substrate 114 (i.e., a solar panel, a flat panel display substrate, a semiconductor wafer, or other workpiece) into and out of the process chamber 100. The access port 130 may be coupled to a transfer chamber and/or other chambers of a substrate processing system.

A gas source 128 is coupled to the chamber body 108 to supply process gases into the processing volume 118. In various embodiments, the process gases may include inert gases, non-reactive gases, and reactive gases. Examples of process gases that may be provided by the gas source 128 include, but not limited to, argon gas (Ar), helium (He), nitrogen gas (N₂), oxygen gas (O₂), hydrogen gas (H₂) and combinations thereof. Other processing gases are contemplated and are included within the scope of the invention.

A pumping port 150 is formed through the bottom 146 of the chamber body 108. A pumping device 152 is coupled to the process volume 118 to evacuate and control the pressure therein. In one embodiment, the pressure level of the process chamber 100 may be maintained in the range of about 10⁻¹⁰ Torr to about 1 Torr. In specific embodiments, the pressure is maintained within the range of about 6 mTorr to about 140 mTorr.

The lid assembly 104 generally includes a target 120 and a ground shield assembly 126 coupled thereto. The target 120 provides a material source that can be sputtered and deposited onto the surface of the substrate 114 during a PVD process. The lid assembly 104 may also include a chamber ceiling 127 which can be on top of the target 120, or around the target 120. In some aspects, the target 120 may act as the ceiling 127. The target 120 may be placed adjacent the chamber ceiling. The target 120 or target plate may be fabricated from a material utilized for deposition species. A very high frequency power (VHF) source 132 and a high-frequency (HF) power source 133 are connected to the target 120 to facilitate sputtering materials from the target 120. The target 120 may be fabricated from any suitable material, including both conductive and non-conductive materials.

The target 120 generally includes a peripheral portion 124 and a central portion 116. The peripheral portion 124 is disposed over the sidewalls 110 of the chamber. The central portion 116 of the target 120 may have a curvature surface slightly extending towards the surface of the substrate 114 disposed on a substrate support 138. The spacing between the target 120 and the substrate support 138 is maintained between about 50 mm and about 150 mm, but other spacing is within the scope of the invention. It is noted that the dimension, shape, materials, configuration and diameter of the target 120 may be varied for specific process or substrate requirements. In one embodiment, the target 120 may further include a backing plate having a central portion bonded and/or fabricated by a material desired to be sputtered onto the substrate surface. The target 120 may also include adjacent tiles or segment materials that together forming the target.

Optionally, the lid assembly 104 may further comprise a magnetron assembly 102 mounted above the target 120 which enhances efficient sputtering materials from the target 120 during processing. Examples of the magnetron assembly include a linear magnetron, a serpentine magnetron, a spiral magnetron, a double-digitated magnetron, a rectangularized spiral magnetron, among others.

The ground shield assembly 126 of the lid assembly 104 includes a ground frame 106 and a ground shield 112. The ground shield assembly 126 may also include other chamber shield member, target shield member, dark space shield, dark space shield frame. The ground shield 112 is coupled to the peripheral portion 124 by the ground frame 106 defining an upper processing region 154 below the central portion of the target 120 in the process volume 118. The ground frame 106 electrically insulates the ground shield 112 from the target 120 while providing a ground path to the chamber body 108 of the process chamber 100 through the sidewalls 110. The ground shield 112 constrains plasma generated during processing within the upper processing region 154 and dislodges target source material from the confined central portion 116 of the target 120, thereby allowing the dislodged target source to be mainly deposited on the substrate surface rather than chamber sidewalls 110. In one embodiment, the ground shield 112 may be formed by one or more work-piece fragments and/or a number of these pieces bonding by processes known in the art, such as welding, gluing, high pressure compression, etc.

The embodiment shown in FIG. 1 includes a shaft 140 extending through the bottom 146 of the chamber body 108 couples to a lift mechanism 144. The lift mechanism 144 is configured to move the substrate support 138 between a lower transfer position and an upper processing position. A bellows 142 circumscribes the shaft 140 and coupled to the substrate support 138 to provide a flexible seal therebetween, thereby maintaining vacuum integrity of the chamber processing volume 118.

A shadow frame 122 may be disposed on the periphery region of the substrate support 138 and is configured to confine deposition of source material sputtered from the target 120 to a desired portion of the substrate surface. A chamber shield 136 may be disposed on the inner wall of the chamber body 108 and have a lip 156 extending inward to the processing volume 118 configured to support the shadow frame 122 disposed around the substrate support 138. As the substrate support 138 is raised to the upper position for processing, an outer edge of the substrate 114 disposed on the substrate support 138 is engaged by the shadow frame 122 and the shadow frame 122 is lifted up and spaced away from the chamber shield 136. When the substrate support 138 is lowered to the transfer position adjacent to the substrate transfer port 130, the shadow frame 112 is set back on the chamber shield 136. Lift pins (not shown) are selectively moved through the substrate support 138 to lift the substrate 114 above the substrate support 138 to facilitate access to the substrate 114 by a transfer robot or other suitable transfer mechanism.

The embodiment of FIG. 1 includes a controller 148 coupled to the process chamber 100. The controller 148 includes a central processing unit (CPU) 160, a memory 158, and support circuits 162. The controller 148 is utilized to control the process sequence, regulating the gas flows from the gas source 128 into the chamber 100, the power and frequency of the VHF and HF power sources to control ion bombardment of the target 120, the density of the plasma and the degree of ionization of the sputtered species. The CPU 160 may be of any form of a general purpose computer processor that can be used in an industrial setting. The software routines can be stored in the memory 158, such as random access memory, read only memory, floppy or hard disk drive, or other form of digital storage. The support circuits 162 are conventionally coupled to the CPU 160 and may comprise cache, clock circuits, input/output subsystems, power supplies, and the like. The software routines, when executed by the CPU 160, transform the CPU into a specific purpose computer (controller) 148 that controls the process chamber 100 such that the processes are performed in accordance with the present invention. The software routines may also be stored and/or executed by a second controller (not shown) that is located remotely from the chamber 100.

During processing, the material sputtered from the target 120 is ionized in the plasma and is deposited on the surface of the substrate 114. The target 120 and the substrate support 138 are biased relative to ground by the VHF power source 132 and the HF power source 133 to maintain a plasma formed from the process gases supplied by the gas source 128, form ions within the plasma, and cause directional sputtering of the ions onto the substrate 114. Ions and excited species within the plasma strike the target 120, causing target material to be dislodged from the target 120. The dislodged target material and process gases experience energetic collisions within the plasma, resulting in the formation of ionic target materials which are accelerated toward the substrate 114, forming a layer on the substrate 114 with same composition as the target 120.

One or more embodiments of the invention are directed to methods of processing a substrate in a physical vapor deposition (PVD) vacuum chamber 100. A target 120 is provided adjacent a ceiling 127 of the chamber. Alternatively, the target 120 can act as the ceiling 127 of the chamber 100, or the ceiling 127 can be located above the magnetron 102. A substrate 114 is placed on a support 128 facing the target 120. A process gas is introduced into the chamber 100 to a selected pressure from a process gas source 128. The pressure of the process gas is adjusted to be high enough to cause ionization of a substantial portion of species sputtered from the target. A capacitively coupled high density plasma is maintained by applying a first power at a first frequency to the target at a frequency sufficiently high to excite kinetic electrons. A second power is applied to the substrate at a second frequency, lower than the first frequency, to generate a sheath potential sufficient to sputter ions from the target onto the substrate to deposit a film of the sputtered ions from the target. One or more of the selected pressure and the sheath potential can be controlled to control the microstructure of the deposited film.

In specific embodiments, the power supplied to the target comprises substantially no direct current component. When direct current is supplied, in particular, to targets composed of non-conductive materials, there is a tendency for an arc to occur within the chamber. Arcing usually results in damage to the substrate being sputtered. Embodiments of the methods are capable of producing and tuning the plasma density and sputter rate without the use of DC power.

The target material is selected based on the desired film being formed. A feature of sputtering is that the film formed has the same composition as the target material. Therefore, the target can be a metal, a pure species, a doped species, etc. with result being that the film is formed of the same material. In one or more embodiments, the target is selected from the group consisting of silicon, doped silicon, zinc oxide, indium tin oxide, transparent conductive oxide, metals and combinations thereof. In a detailed embodiment, the target is silicon, with or without a dopant.

Typical sputtering is preformed at pressures well below 2 mTorr. At these pressures there is little or no ionization (generally <0.1%) of the sputtered species within the plasma. Embodiments of the present invention use relatively high gas pressure within the chamber in combination with the VHF plasma, resulting in a marked effect on the ionization of the sputtered species. Without being bound by any particular theory of operation, it is believe that higher pressures result in higher density plasmas with more energetic collisions between plasma species and target species. In detailed embodiments the selected pressure is in the range of about 4 mTorr to about 200 mTorr. In other detailed embodiments, the selected pressure is in the range of about 6 mTorr to about 140 mTorr. In further detailed embodiments the selected pressure is in the range of about 10 mTorr to about 120 mTorr. In other detailed embodiments the selected pressure is in the range of about 20 mTorr to about 110 mTorr, or in the range of about 20 mTorr to about 100 mTorr, or in the range of about 30 mTorr to about 90 mTorr, or in the range of about 40 mTorr to about 70 mTorr, or in the range of about 50 mTorr to about 60 mTorr. In some detailed embodiments, the selected pressure is greater than about 4, 5, 6, 7, 8, 9, 10, 15, 20, 25, 30, 35, 40, 45, 50, 55, 60, 65, 70, 75, 80, 85, 90, 95, 100, 105, 110, 115, 120, 125, 130, 135, 140, 145, 150, 155, 160, 165, 170, 175, 180, 185, 190 or 195 mTorr. Other detailed embodiments have a pressure in the range between any of the minimum values and maximum values listed. At about 6 mTorr, the sputtered material will be about 5% ionized. At greater than about 140 mTorr, about 100% of the sputtered material will be ionized. One skilled in the art would understand that these ionization percentages are estimates and are not intended to limit the scope of the invention.

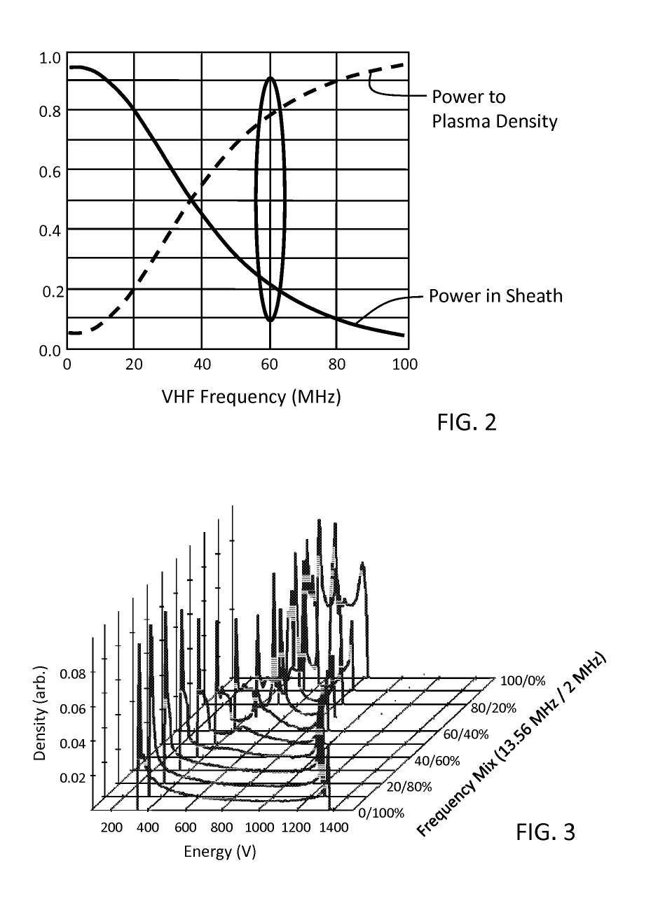

Without being bound by any particular theory of operation, it is believed that the first frequency (VHF frequency) contributes to both the formation of the plasma and the sputtering rate. FIG. 2 shows a graph of the power contribution ratio as a function of the first frequency. It can be seen that the higher the first frequency the more power is contributed to the formation of the plasma and the overall plasma density, with a lesser amount supplying energy to cause sputtering from the target. The ratio of powers contributed at 60 MHz is circled in FIG. 2 because this is a commonly used, although not necessarily preferred, first frequency. At 60 MHz it can be seen that about 75-80% of the supplied power is instrumental in creating a dense plasma, with the remaining power causing sputtering. FIG. 2 shows that a higher frequency power can result in a dense plasma with very little sputtering. In some embodiments, the first frequency is in the range of about 40 MHz to about 100 MHz. The first frequency of the other embodiments is in the range of about 60 MHz and about 100 MHz, or in the range of about 50 MHz to about 100 MHz, or in the range of about 50 MHz to about 90 MHz, or in the range of about 60 MHz to about 80 MHz. In a specific embodiment, the first frequency is about 60 MHz. In other embodiments, the first frequency is greater than about 40, 50, 60, 70, 80 or 90 MHz. In further embodiments, the first frequency is less than about 100 MHz.

In a specific embodiment, the first power is at least about 4 kW. In other embodiments, the first power is at least about 1, 2, 3, 4, 5, 6 or 7 kW. In further embodiments, the first power is less than about 8 kW. In additional detailed embodiments, the first power is in the range of any of the minimum to maximum values.

The second frequency, or high frequency power, is applied to the substrate 114, or substrate stand 138. Without being bound by any particular theory of operation, it is believed that the rate, and the ion energy distribution of the plasma, causes ions in the plasma to accelerate toward the substrate 114. In a specific embodiment, the second frequency is effective to cause ions within the plasma to move perpendicularly toward the substrate with controlled energy.

In one or more embodiment, the second frequency is at least about 2 MHz. In other embodiments, the second frequency is at least about 13.56 MHz. In further embodiments, the second frequency is a combination of 2 MHz and 13.56 MHz contributions. FIG. 3 shows a graph of the density of the ion energy distribution within the plasma as a function of the relative contribution of the 2 MHz and 13.56 MHz frequencies. The individual contribution of the 2 MHz and the 13.56 MHz frequencies can be tuned manually by the user or by the controller 148. For example, the second frequency can range from entirely 2 MHz to entirely 13.56 MHz, or any point in between. In some embodiments, the second frequency is in the range of about 400 kHz to about 14 MHz In other embodiments, the second frequency is greater than about 400 kHz, 500 kHz, 600 kHz, 700 kHz, 800 kHz, 900 kHz, 1 MHz, 2 MHz, 3 MHz, 4 MHz, 5 MHz, 6 MHz, 7 MHz, 8 MHz, 9 MHz, 10 MHz, 12 MHz, 13 MHz, 13.56 MHz In other embodiments, the second frequency is less than about 14 MHz. In additional embodiments, the second frequency is between any of the minimum frequencies and the maximum frequencies listed.

In some specific embodiments, the second power is in the range of about 0 watts to about 1000 watts. In other specific embodiments, the second power is in the range of about 0 watts to about 600 watts. In further specific embodiments, the second power is greater than about 0, 50, 100, 150, 200, 250, 300, 400, 500, 600, 700, 800 or 900 watts. In additional specific embodiments, the second power is less than about 1000 watts. In other embodiments, the second power is in the range of about any of the lower values to about any of the upper values listed. If the second power is too high, the ions hitting the substrate can cause back sputtering from the surface of the substrate, which may be desirable under some circumstances.

In other embodiments, a third power at third frequency is applied to the target. In some embodiments, the third frequency in the range of about 400 kHz to 14 MHz can increase the sputter rate (deposition rate) from the target. The third frequency can be any of the values listed for the second frequency. In some embodiments, the third power in the range of about 500 watts to about 4 kilowatts. In other embodiments, the third power is greater than about 500, 600, 700, 800, 900, 1000, 1100, 1200, 1300, 1400, 1500, 1600, 1700, 1800, or 1900 watts. In other embodiments, the third power is less than about 2000 watts.

The gas used for plasma processing can be selected from any suitable plasma gas. Suitable gases include, but are not limited to, helium, neon, argon, krypton, xenon, radon, hydrogen, nitrogen, oxygen and mixtures thereof. In detailed embodiments of the invention, the process gas comprises argon. In various embodiments the process gas further comprises a percentage of hydrogen. In some embodiments, the percentage of hydrogen is up to about 40%, 35%, 30%, 25%, 20%, 15%, 10%, 5%. In other embodiments, the percentage of hydrogen is in the range of about 1% to about 15%, or in the range of about 2% to about 10%. In a detailed embodiment, the percentage of hydrogen is up to about 30%. In other detailed embodiments, the percentage of hydrogen is about 2.8%.

Silicon dangling bonds can form as a result of routine silicon processing. Dangling bonds include silicon radicals which can negatively affect the film formation around the radical. In a detailed embodiment of the invention, the target comprises silicon and the percentage of hydrogen is controlled to reduce the amount of silicon dangling bonds in the film.

The substrate support 138 can include a heating or cooling system, allowing the temperature of the support 138 and the substrate 114 to be changed. In one or more embodiments of the invention, the temperature of the substrate is controlled. In some detailed embodiments, the temperature can be changed during processing to control the microstructure of the resultant film.

In various specific embodiments of the invention, the method further comprises adjusting one or more of the selected pressure, the first frequency, the second frequency, the third frequency and the temperature.

Other embodiments of the invention are directed to methods of processing a substrate in a physical vapor deposition (PVD) vacuum chamber comprising performing a deposition step with deposition parameters comprising a plasma pressure, very high frequency power and high frequency power. A target is provided adjacent a ceiling of the chamber and a substrate is placed on a support facing the target. A process gas is introduced into the chamber to a selected pressure. A high density plasma is generated from the process gas by applying very high frequency power to the target. A sheath potential is generated by applying high frequency power to the substrate. The high frequency power being sufficient to ionize material sputtered from the target. A film is deposited on the substrate from the ions generated from the material sputtered from the target. The microstructure of the film is controlled by adjusting one or more of the pressure and high frequency power.

In some embodiments, the pressure and the high frequency power can be reduced to form an amorphous film. In other embodiments, one or both of the high frequency power and the pressure can be increased to increase the sputtered ion flux or the ion energy to form a nano-crystalline film. In detailed embodiments, the target comprises silicon and the process gas comprises a mixture of argon and hydrogen to terminate dangling silicon bonds in the film. The substrate of specific embodiments comprises a solar cell.

### EXAMPLES

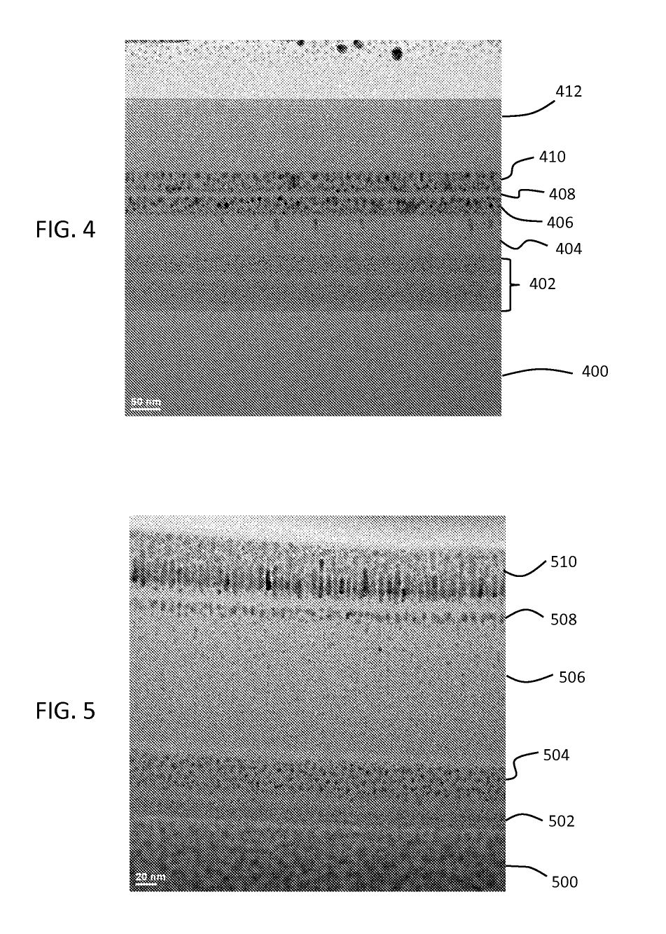

FIG. 4 shows a transmission electron micrograph (TEM) image of a multilayer deposition of silicon with a controlled microstructure. An argon plasma was generated by applying very-high frequency power to a silicon target at 60 MHz with a power of 4 kW. The water support was held at 350° C., but the wafer temperature was not measured. The percent ionization of the sputtered species was modified by controlling the pressure. The ion energy (deposition rate) was modified by controlling the power of a 2 MHz high frequency bias on the substrate. The glass substrate 400, shown on the bottom, has several visible layers deposited thereon. In purely relative terms, layer 402 was generated with a low ionization percentage (low pressure) and a high ionization energy (high bias power). Region 404 was generated by deposition at low ionization percentage and low ionization energy. Both regions 402 and 404 resulted in an amorphous silicon layer, although it can be seen that region 402 has small microcrystal formation. A crystalline region 406 was deposited at high ionization percentage and high ionization energy. A small amorphous layer 408 is next generated in the same fashion as that of layer 404. A subsequent crystalline layer 410 follows using the same conditions as region 406. The top layer 412 is an amorphous silicon deposition done at lower ionization percentage and low ionization energy, as in layer 404.

### Example 1

A multilayer deposition was formed on a glass substrate using a PVD chamber as described earlier. An argon plasma was generated by applying very-high frequency power to a silicon target at 60 MHz with a power of 4 kW. The substrate support was heated to 200° C. and the ionization percentage was controlled by adjusting the plasma gas pressure and the ionization percentage was controlled by adjusting the power of the 2 MHz high-frequency bias on the substrate. FIG. 5 shows a TEM of a multilayer deposition. See Table 1 for the deposition conditions for each of the layers.

TABLE 1

| | | |
|---|---|---|
| Layer | Pressure (mTorr) | 2 MHz Bias Power (watts) |

| | |
|---|---|
| 500 | Glass Substrate |

| | | |
|---|---|---|
| 502 | 45 | 100 |
| 504 | 45 | 250 |
| 506 | 60 | 50 |
| 508 | 6 | 0 |
| 510 | 70 | 450 |

### Example 2

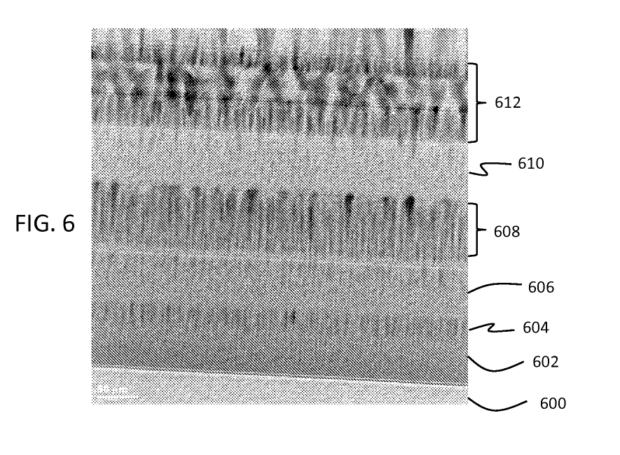

A multilayer deposition was formed on a glass substrate using a PVD chamber as described earlier. An argon plasma was generated by applying very-high frequency power to a silicon target at 60 MHz with a power of 4 kW. The substrate support was heated to 100° C. and the ionization percentage was controlled by adjusting the plasma gas pressure and the ionization percentage was controlled by adjusting the power of the 2 MHz high-frequency bias on the substrate. FIG. 6 shows a TEM of a multilayer deposition. See Table 2 for the deposition conditions for each of the layers.

TABLE 2

| | | |
|---|---|---|
| Layer | Pressure (mTorr) | 2 MHz Bias Power (watts) |

| | |
|---|---|
| 600 | Glass Substrate |
| 602 | Amorphous (low pressure, no bias power) |

| | | |
|---|---|---|
| 604 | 6 | 100 |

| | |
|---|---|
| 606 | Amorphous (low pressure, no bias power) |

| | | |
|---|---|---|
| 608 | 6 | 300 |

| | |
|---|---|
| 610 | Amorphous (low pressure, no bias power) |

| | | |
|---|---|---|
| 612 | 6 | 450 |

An amorphous layer 602, 606, 610 separate the crystalline layers. This was done to make the crystalline layers easier to visually distinguish. The amorphous layers were deposited at low pressure without an applied bias power.

Although the invention herein has been described with reference to particular embodiments, it is to be understood that these embodiments are merely illustrative of the principles and applications of the present invention. It will be apparent to those skilled in the art that various modifications and variations can be made to the method of the present invention without departing from the spirit and scope of the invention. Thus, it is intended that the present invention include modifications and variations that are within the scope of the appended claims and their equivalents.

1. A method of processing a substrate in a physical vapor deposition (PVD) vacuum chamber comprising:
providing a target adjacent a ceiling of the chamber;
placing a substrate on a support facing the target;
introducing a process gas into the chamber to a selected pressure, the pressure being sufficient to cause ionization of a substantial portion of species sputtered from the target;
maintaining a capacitively coupled high density plasma by applying a first power at a first frequency to the target at a frequency sufficiently high to excite kinetic electrons;
applying a second power to the substrate at a second frequency lower than the first frequency to generate a sheath potential sufficient to deposit a film of sputtered ions from the plasma; and
controlling one or more of the selected pressure and the sheath potential to control microstructure of the film.

2. The method of claim 1, wherein the target is selected from the group consisting of silicon, doped silicon, zinc oxide, indium tin oxide, transparent conductive oxide, metals and combinations thereof.

3. The method of claim 1, wherein substantially no direct current power is applied to the target.

4. The method of claim 1, wherein the selected pressure is in the range of about 6 mTorr to about 140 mTorr.

5. The method of claim 1, wherein the selected pressure is in the range of about 40 mTorr to about 70 mTorr.

6. The method of claim 1, wherein the first frequency is about 60 MHz and the first power is about 4 kW.

7. The method of claim 1, wherein the second power is in the range of about 0 watts to about 600 watts.

8. The method of claim 7, wherein the second frequency is about 2 MHz.

9. The method of claim 7, wherein the second frequency is about 13.56 MHz.

10. The method of claim 1, wherein the second frequency is effective to cause ions within the plasma to move perpendicularly toward the substrate.

11. The method of claim 1, further comprising a third power at third frequency applied to the target, the third frequency in the range of about 400 kHz to about 14 MHz to increase the sputter rate from the target, the third power in the range of about 500 watts to about 2 kilowatts.

12. The method of claim 1, further comprising adjusting one or more of the selected pressure and the first frequency to change number of ions hitting the substrate.

13. The method of claim 1, further comprising adjusting the second power to change the energy of the sputtered ions.

14. The method of claim 1, wherein the process gas comprises argon.

15. The method of claim 14, wherein the process gas further comprises a percentage of hydrogen.

16. The method of claim 15, wherein the percentage of hydrogen is up to about 30%.

17. The method of claim 15, wherein the percentage of hydrogen is in the range of about 2% to about 10%.

18. The method of claim 15, wherein the percentage of hydrogen is about 2.8%.

19. The method of claim 15, wherein the target comprises silicon and the percentage of hydrogen is controlled to reduce silicon dangling bonds in the film.

20. The method of claim 1, further comprising controlling the temperature of the substrate.

21. A method of processing a substrate in a physical vapor deposition (PVD) vacuum chamber comprising:
performing a deposition step with deposition parameters comprising a plasma pressure, very high frequency power and high frequency power, the deposition comprising:
providing a target adjacent a ceiling of the chamber;
placing a substrate on a support facing the target;
introducing a process gas into the chamber to a selected pressure;
generating a high density plasma from the process gas by applying very high frequency power to the target,
generating a sheath potential by applying high frequency power to the substrate, the high frequency power being sufficient to substantially ionize material sputtered from the target;
depositing a film on the substrate from the ions generated from the material sputtered from the target; and
controlling microstructure of the film by adjusting one or more of the selected pressure and high frequency power.

22. The method of claim 21, wherein the pressure is reduced and the high frequency power is reduced to form an amorphous film.

23. The method of claim 21, wherein one or both of the high frequency power and the pressure is increased to increase sputtered ion flux or ion energy to form a crystalline film.

24. The method of claim 21, wherein the target comprises silicon and the process gas comprises a mixture of argon and hydrogen, the mixture being effective to reduce dangling silicon bonds in the film.

25. The method of claim 24, wherein the substrate comprises a solar cell.
